(19) United States
(12) Patent Application Publication
(10) Pub. No.: US 2025/0164586 A1
(43) Pub. Date: May 22, 2025

(54) MAGNETIC SENSOR MODULE AND METHOD FOR DETERMINING OPERATION CONDITION OF MAGNETIC SENSOR MODULE

(71) Applicant: HAMAMATSU PHOTONICS K.K., Hamamatsu-shi, Shizuoka (JP)

(72) Inventors: Norihisa KATO, Hamamatsu-shi, Shizuoka (JP); Masaki YAMADA, Hamamatsu-shi, Shizuoka (JP); Koji TAKEMIYA, Hamamatsu-shi, Shizuoka (JP); Masato KITABAYASHI, Hamamatsu-shi, Shizuoka (JP)

(73) Assignee: HAMAMATSU PHOTONICS K.K., Hamamatsu-shi, Shizuoka (JP)

(21) Appl. No.: 18/839,519

(22) PCT Filed: Oct. 19, 2022
(86) PCT No.: PCT/JP2022/038974

§ 371 Date: Aug. 19, 2024

(30) Foreign Application Priority Data
Feb. 25, 2022 (JP) 2022-028260

(51) Int. Cl. G01R 33/26; G01R 35/00

(52) U.S. Cl. CPC G01R 33/26; G01R 35/00

(57) ABSTRACT

A magnetometer module includes a cell, a pump laser light source, a photodiode configured to detect an intensity of pump light, a probe laser light source, a photodiode element configured to detect an intensity of probe light, a differential amplifier configured to generate a magnetism detection signal based on the probe light that has passed through the cell, and a control circuit configured to perform at least one of first determination processing of determining a driving condition of the light source based on the intensity of the pump light detected by the photodiode while controlling the light source and performing wavelength sweep on the pump light and second determination processing of determining a driving condition of the light source based on the intensity of the probe light detected by the photodiode element while controlling the light source and performing wavelength sweep on the probe light.

### TECHNICAL FIELD

One aspect of an embodiment relates to a magnetometer sensor module and a method for determining an operation condition of the magnetometer module.

### BACKGROUND ART

An optically pumped magnetometer that measures a magnetic field has conventionally been used (see Patent Literature 1 below). The optically pumped magnetometer includes a cell containing an alkali metal, a light source that causes pump light to enter the cell, a light source that causes probe light to enter the cell and cross the pump light, and a detection unit that detects a signal reflecting a rotation angle of a polarization plane of the probe light. According to the optically pumped magnetometer having such a configuration, a weak magnetic field can be measured by using the spin polarization of the alkali metal excited by optical pumping.

### CITATION LIST

### Patent Literature

Patent Literature 1: Japanese Unexamined Patent Publication No. 2016-50837

### SUMMARY OF INVENTION

### Technical Problem

In the conventional optically pumped magnetometer as described above, it is important to adjust the operation condition of the light sources so as to ensure the sensitivity of magnetic field measurement. It is desirable to adjust the operation condition of the light sources in response to a change in the state of the internal temperature of the cell, the state of the pressure of the cell, and the like, but there has been a tendency that it is difficult to realize adjustment corresponding to the change in the states of the cell.

One aspect of an embodiment has been made in view of such a problem, and an object thereof is to provide a magnetometer module and a method for determining an operation condition of the magnetometer module capable of enhancing measurement sensitivity according to a change in the state of a cell.

### Solution to Problem

A magnetometer module according to a first aspect of the embodiment includes a cell in which an alkali metal is enclosed, a first light source configured to emit pump light for exciting an atom of the alkali metal, a first detector configured to detect an intensity of the pump light, a second light source configured to emit probe light for detecting a change in a magnetic rotation angle caused by spin polarization of the atom in an excited state, a second detector configured to detect an intensity of the probe light, a signal output unit configured to detect a change in a polarization plane of the probe light based on the probe light having passed through the cell and generate an output signal related to magnetism in the cell, and a control unit configured to perform at least one of first determination processing of determining a driving condition of the first light source based on the intensity of the pump light detected by the first detector while controlling the first light source and performing wavelength sweep on the pump light and second determination processing of determining a driving condition of the second light source based on the intensity of the probe light detected by the second detector while controlling the second light source and performing wavelength sweep on the probe light.

Alternatively, a method for determining an operation condition of a magnetometer module according to a second aspect of the embodiment is a method for determining an operation condition of a magnetometer module, the magnetometer module including a cell in which an alkali metal is enclosed, a first light source configured to emit pump light for exciting an atom of the alkali metal, a first detector configured to detect an intensity of the pump light, a second light source configured to emit probe light for detecting a change in a magnetic rotation angle caused by spin polarization of the atom in an excited state; a second detector configured to detect an intensity of the probe light, and a signal output unit configured to detect a change in a polarization plane of the probe light based on the probe light having passed through the cell and generate an output signal related to magnetism in the cell, the method including at least one of performing first determination processing of determining a driving condition of the first light source based on the intensity of the pump light detected by the first detector while controlling the first light source and performing wavelength sweep on the pump light, and performing second determination processing of determining a driving condition of the second light source based on the intensity of the probe light detected by the second detector while controlling the second light source and performing wavelength sweep on the probe light.

According to the first aspect or the second aspect, the intensity of the pump light emitted from the first light source toward the cell is detected by the first detector, the intensity of the probe light emitted from the second light source toward the cell is detected by the second detector, and an output signal related to magnetism is generated based on the probe light having passed through the cell. In the magnetometer module, either the processing of determining the driving condition of the first light source based on the intensity of the pump light while performing wavelength sweeping on the pump light or the processing of determining the driving condition of the second light source based on the intensity of the probe light while performing wavelength sweeping on the probe light is performed. This makes it possible to set the light source in an appropriate driving condition even though a change occurs in the state of the cell, and the measurement sensitivity can be enhanced according to a change in the state of the cell.

### Advantageous Effects of Invention

According to any of the aspects of the present disclosure, measurement sensitivity can be enhanced according to a change in the state of the cell.

### BRIEF DESCRIPTION OF DRAWINGS

FIG. 1 is a schematic configuration diagram of a magnetometer module 1 according to an embodiment.

FIG. 2 is a graph illustrating a change in a probe light intensity signal with respect to a change in a supply current of a coil 10a.

FIG. 3 is a graph illustrating a change in a probe light intensity signal with respect to a change in a supply current of a coil 10c.

FIG. 4 is a graph illustrating a change in a probe light intensity signal with respect to a change in a supply current of a coil 10b.

FIG. 5 is a graph illustrating a change in a pump light intensity signal with respect to a change in a wavelength of pump light.

FIG. 6 is a graph illustrating characteristics of an absorption cross section σ(ν) and a polarization rotation angle θ of alkali metal with respect to a wavelength ν of probe light, and characteristics of intensity of a magnetism detection signal with respect to the wavelength ν of probe light.

FIG. 7 is a graph illustrating a relationship between probe light intensity and an intensity value Sₒᵤₜ of a magnetism detection signal, a noise value Nₒᵤₜ of the magnetism detection signal, and a value SNₒᵤₜ of an S/N of the magnetism detection signal.

FIG. 8 is a flowchart illustrating a procedure of a method for determining an operation condition according to an embodiment.

### DESCRIPTION OF EMBODIMENTS

Hereinafter, an embodiment of the present invention will be described in detail with reference to the accompanying drawings. In the description, the same reference numeral is used for the same component or a component having the same function, and redundant description is omitted.

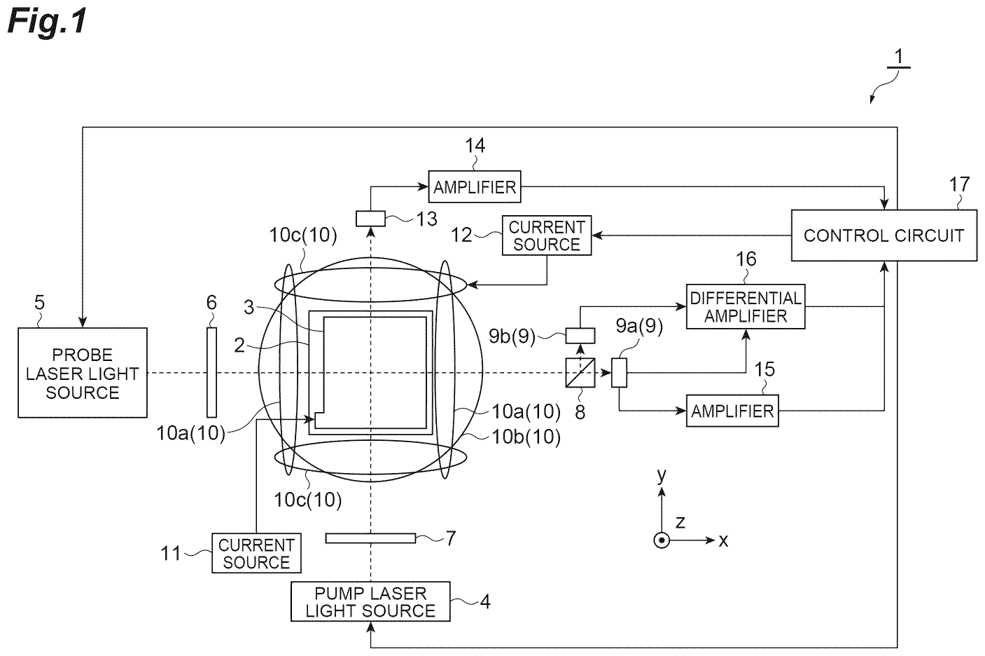

FIG. 1 is a schematic configuration diagram of a magnetometer module 1 according to an embodiment. The magnetometer module 1 is a device that measures a magnetic field using optical pumping. The magnetometer module 1 is used for the purpose of biological measurements such as magnetoencephalography or magnetospinography, or for the purpose of material analysis such as NMR (Nuclear Magnetic Resonance), but the purpose of use is not limited to these purposes. In FIG. 1, a y axis is taken in a direction along an incident direction of pump light with respect to a cell to be described later, an x axis is taken in a direction perpendicular to the y axis, which is a direction along an incident direction of probe light with respect to the cell, and a z axis is taken in a direction perpendicular to the y axis and the x axis. In FIG. 1, a propagation path of light is indicated by a dotted line, and a transmission path of power and a signal is indicated by a solid line with an arrow.

The magnetometer module 1 includes a cell 2, a heater 3, a pump laser light source (first light source) 4, a probe laser light source (second light source) 5, a ½ wave plate 6, a ¼ wave plate 7, a polarization beam splitter 8, a photodiode (detector) 9, a magnetic field correction coil 10, current sources 11 and 12, a photodiode (detector) 13, amplifiers 14 and 15, a differential amplifier (signal output unit) 16, and a control circuit (control unit) 17. Hereinafter, details of each component of the magnetometer module 1 will be described.

The cell 2 has, for example, a substantially rectangular parallelepiped and bottomed cylindrical shape, and is made of a material having optical transparency with respect to pump light and probe light described later. The material of the cell 2 is, for example, quartz, sapphire, silicon, Kovar glass, borosilicate glass, or the like. The cell 2 contains an alkali metal and a filling gas. The alkali metal contained in the cell 2 may be, for example, at least one or more of lithium (Li), sodium (Na), potassium (K), rubidium (Rb), and cesium (Cs). The filling gas suppresses relaxation of spin polarization of alkali metal vapor. The filling gas also protects alkali metal vapor and suppresses noise emission. The filling gas may be, for example, an inert gas such as helium (He), neon (Ne), argon (Ar), krypton (Kr), xenon (Xe), or nitrogen (N2).

The heater 3 is provided close to the cell 2 and heats the inside of the cell 2. The heater 3 generates heat according to the current supplied from the current source 11. The heater 3 vaporizes the alkali metal inside the cell 2 and controls the vapor density thereof by controlling the supply current of the current source 11 so that the internal temperature of the cell 2 becomes a predetermined temperature (for example, 180° C.) based on a measurement signal from a temperature sensor not illustrated that measures the internal temperature of the cell 2.

A pump laser light source 4 emits pump light in a linearly polarized state for exciting alkali metal atoms. The pump laser light source 4 may form the pump light into any size. The alkali metal atoms contained in the cell 2 are excited by the pump light, and the directions of spins are aligned (spin polarization). The wavelength of the pump light is set according to the type of atoms constituting the vapor of the alkali metal (more specifically, the wavelength of the absorption line). In the present embodiment, the driving condition of the pump laser light source 4 is determined by a control circuit 17, and the intensity and wavelength of the pump light to be emitted from the pump laser light source 4 can be adjusted by the control of the control circuit 17 (details will be described later). To realize such control, the pump laser light source 4 has a function capable of controlling the oscillation wavelength using an external resonator, a configuration capable of controlling the oscillation wavelength by controlling the temperature of a laser element, or the like.

A probe laser light source 5 emits probe light in a linearly polarized state for detecting a change in the magnetic rotation angle caused by the spin polarization of the alkali metal atoms in the excited state. The probe laser light source 5 may form the probe light into any size. When the probe light passes through the vapor of the alkali metal, the probe light is affected by the state of spin polarization of the alkali metal atoms, and causes magnetic rotation. Detecting the change in the polarization plane of the probe light due to the magnetic rotation makes it possible to derive the state of spin polarization. The wavelength of the probe light is set according to the type of atoms constituting the vapor of the alkali metal (more specifically, the wavelength of the absorption line). In the present embodiment, the driving condition of the probe laser light source 5 is determined by the control circuit 17, and the intensity and wavelength of the probe light to be emitted from the probe laser light source 5 can be adjusted by the control of the control circuit 17 (details will be described later). To realize such control, the probe laser light source 5 has a function capable of controlling the oscillation wavelength using an external resonator, a configuration capable of controlling the oscillation wavelength by controlling the temperature of a laser element, or the like.

In the present embodiment, a direction (positive direction along the y axis) in which the pump light transmits through the cell 2 and a direction (positive direction along the x axis) in which the probe light transmits through the cell 2 are set to directions perpendicular to each other.

The ½ wave plate 6 is an optical element that is fixed on an optical path of the probe light between the probe laser light source 5 and the cell 2 and rotates a polarization direction of the probe light. The ½ wave plate 6 is provided together with the polarization beam splitter 8 to function as a beam splitter that enables adjustment of a branching ratio of probe light. The ¼ wave plate 7 is an optical element that is fixed on an optical path of the pump light between the pump laser light source 4 and the cell 2 and changes the polarization state of the pump light from linearly polarized light to circularly polarized light.

The polarization beam splitter 8 separates a first light component having a first polarization plane and a second light component having a polarization plane orthogonal to the first light component included in the probe light transmitted through the cell 2 and entering. For example, the first polarization plane is inclined at 45 degrees with respect to the polarization plane of the probe light emitted from the probe laser light source 5. The second light component is inclined at 90 degrees with respect to the first polarization plane. Thus, when no magnetic field is applied to the cell 2, the amounts of light of the probe light having the first and second polarization planes are equal. On the other hand, when a magnetic field is applied to the cell 2, the spin polarization of the alkali metal atom changes, the polarization plane changes when the probe light passes through the inside of the cell 2, and thus the balance of the light amount changes according to the magnetic field intensity. The polarization beam splitter 8 emits the first light component in the positive direction of the x axis and emits the second light component in the positive direction of the y axis according to the change in the balance.

The photodiode 9 includes two photodiode elements 9a and 9b, and is a detection unit that detects, outside the cell 2, the probe light orthogonal to the pump light inside the cell 2. The photodiode element 9a is disposed in the positive direction of the x axis with respect to the polarization beam splitter 8. The first light component transmitted through the polarization beam splitter 8 enters the photodiode element 9a. The photodiode element 9a generates and outputs a signal corresponding to the intensity of the first light component. The photodiode element 9b is disposed in the positive direction of the y axis with respect to the polarization beam splitter. The second light component reflected by the polarization beam splitter 8 enters the photodiode element 9b. The photodiode element 9b generates and outputs a signal corresponding to the intensity of the second light component.

The differential amplifier 16 generates and amplifies a differential signal indicating a difference between the output signal of the photodiode element 9a and the output signal of the photodiode element 9b as a magnetism detection signal obtained by detecting a change in the polarization plane in the probe light transmitted through the cell 2, and outputs the magnetism detection signal to the control circuit 17. The voltage value of the magnetism detection signal indicates the intensity of the magnetic field in the cell 2.

The amplifier 15 amplifies and generates the output signal of the photodiode element 9a as a signal (probe light intensity signal) obtained by detecting the intensity of the probe light transmitted through the cell 2.

The amplifier 15 outputs the amplified probe light intensity signal to the control circuit 17. Since the amplifier 15 uses the voltage and the differential amplifier 16 uses the current among the output signals of the photodiode element 9a, the photodiode element 9a can be shared, and the configuration of the device can be simplified.

The photodiode 13 is a detection unit that detects, outside the cell 2, the pump light transmitted through the inside of the cell 2. The photodiode 13 generates and outputs a signal (pump light intensity signal) corresponding to the intensity of the pump light that has transmitted through the cell 2. The amplifier 14 amplifies the pump light intensity signal output from the photodiode 13 and outputs the amplified signal to the control circuit 17.

The magnetic field correction coil 10 is a coil group that is provided around the cell 2 and corrects and cancels an environmental magnetic field such as geomagnetism in a space where the cell 2 is present in three axial directions of the x axis, the y axis, and the z axis. The magnetic field correction coil 10 includes, for example, three coils 10a, 10c, and 10b wound around the x-axis direction, the y-axis direction, and the z-axis direction. Each of the three coils 10a, 10c, and 10b generates a correction magnetic field along the x axis, the y axis, and the z axis with the current supplied from the current source 12. The magnetic field correction coil 10 operates to cancel the environmental magnetic field in the space where the cell 2 is present through the control of the supply current to the coils 10a, 10c, and 10b of the current source 12 with the control circuit 17.

The control circuit 17 derives a magnetic field inside the cell 2 based on the magnetism detection signal from the differential amplifier 16, and outputs the derived result to the outside. The control circuit 17 also has a function of controlling magnetic field correction with the magnetic field correction coil 10 and a function of determining operation conditions (driving conditions) of the pump laser light source 4 and the probe laser light source 5.

That is, as a function of controlling the magnetic field correction, the control circuit 17 adjusts the correction magnetic field by adjusting the supply current to the coils 10a, 10b, and 10c based on the pump light intensity signal output from the amplifier 14. More specifically, the control circuit 17 observes the change in the pump light intensity signal while changing the supply current to each of the coils 10a, 10b, and 10c, and adjusts each supply current so that the change in the pump light intensity has an extreme value. Correction of the environmental magnetic field in three axial directions is thus controlled.

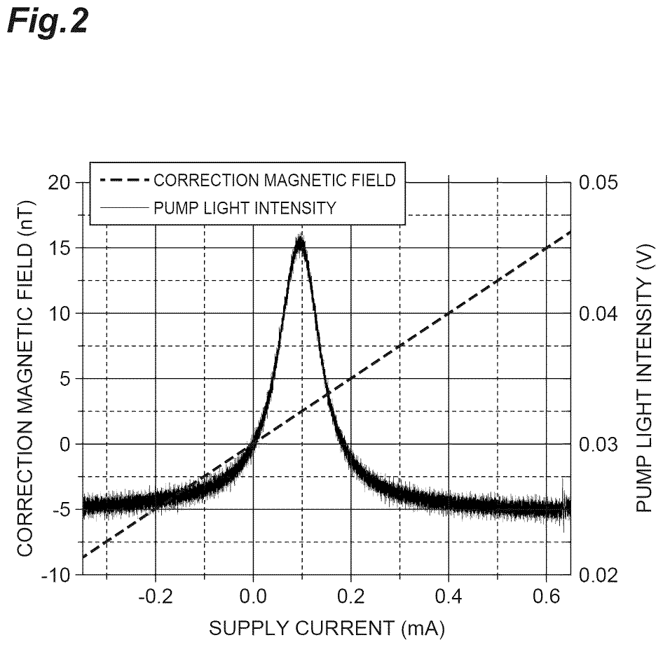

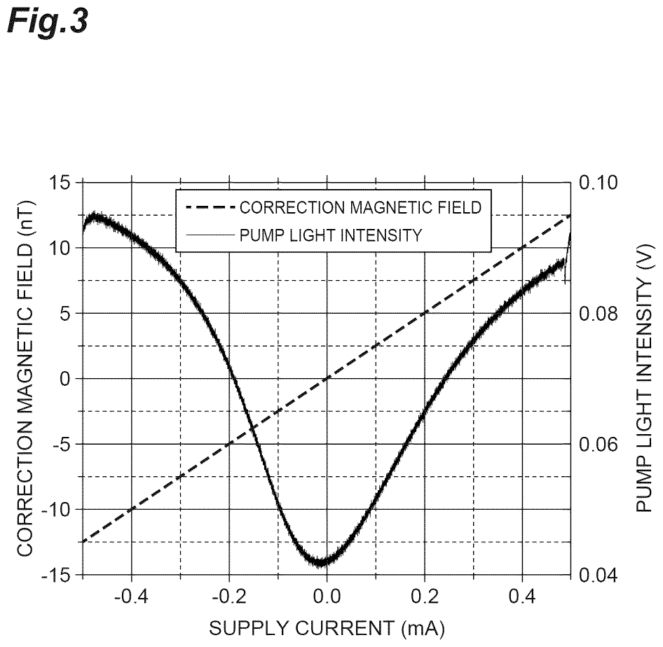

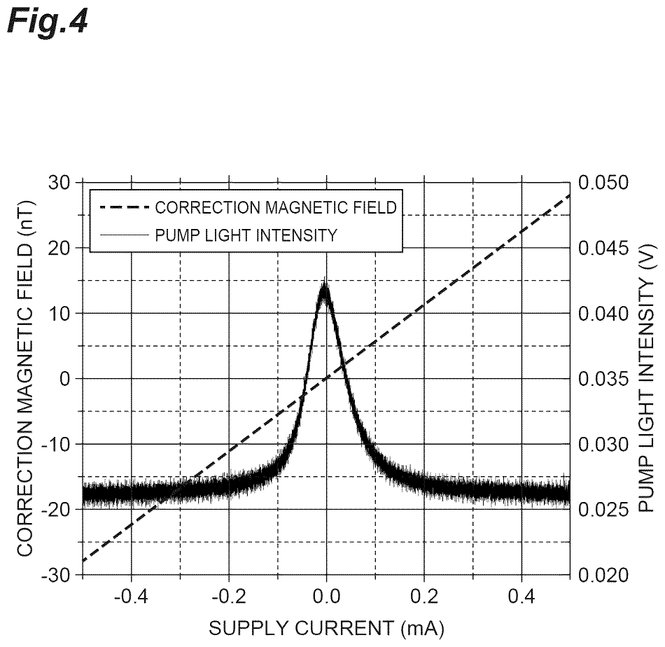

A specific example of the control of the magnetic field correction will be described with reference to FIGS. 2 to 4. FIGS. 2 to 4 are graphs illustrating a change in the pump light intensity signal with respect to a change in the supply current of each of the coils 10a, 10c, and 10b. As indicated, when the correction magnetic field along the x axis and the z axis is changed, the pump light intensity changes to have a local maximum value, and when the correction magnetic field along the y axis direction is changed, the pump light intensity changes to have a local minimum value. The control circuit 17 adjusts the supply current for each of the coils 10a, 10c, and 10b to a value corresponding to these extreme values. The fact that the intensity of the pump light takes an extreme value means that the environmental magnetic field becomes a zero magnetic field and the number of alkali atoms in the ground state in the cell 2 is small. Adjustment of the correction magnetic field with the control circuit 17 is performed using such a phenomenon.

In addition, as a function of determining the operation condition of the pump laser light source 4, the control circuit 17 determines the operation condition of the pump laser light source 4 by adjusting the wavelength of the pump light to be emitted from the pump laser light source 4 based on the pump light intensity signal. More specifically, the control circuit 17 changes the oscillation wavelength of the pump laser light source 4, observes the change in the pump light intensity signal while performing wavelength sweeping on the pump light, and controls the pump laser light source 4 so as to have an oscillation wavelength (a laser driving condition indicating the oscillation wavelength, for example, a laser driving temperature or the like) with which the change in the pump light intensity has a local minimum value. This makes it possible to determine the wavelength of the pump light without using a wavelength meter.

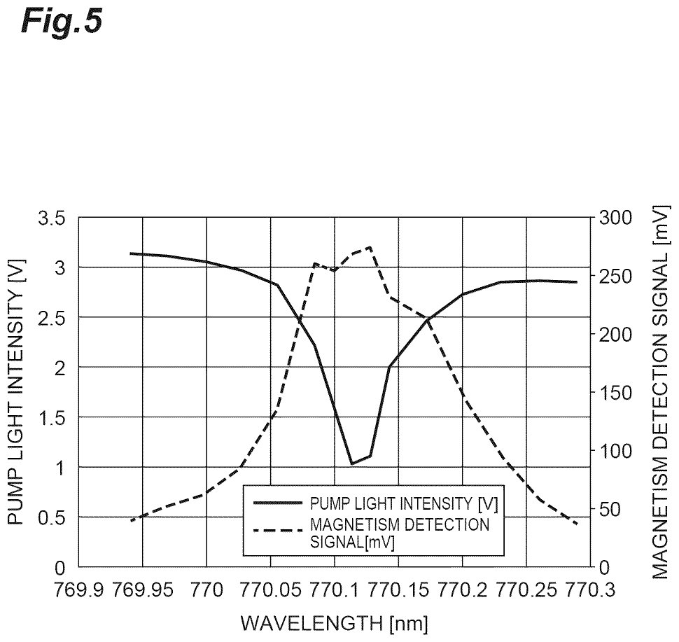

A specific example of determining the operation condition of the pump laser light source 4 will be described with reference to FIG. 5. FIG. 5 is a graph illustrating a change in a pump light intensity signal with respect to a change in a wavelength of pump light. As indicated, the fact that the pump light intensity is minimized means that the wavelength of the pump light at that time corresponds to the absorption spectrum of the alkali metal atoms in the cell 2, and the absorption of the pump light in the cell 2 is maximized at the wavelength of the pump light. At that time, the voltage value of the magnetism detection signal from the differential amplifier 16 also becomes maximum at the wavelength of the pump light. By using such a property, the control circuit 17 can correct the deviation of the oscillation wavelength of the pump laser light source 4 from the desired wavelength (deviation between the set wavelength and the actual output wavelength) by using the result of measuring the intensity of the pump light and adjusting the deviation without using a wavelength meter.

Further, as a function of determining the operation condition of the probe laser light source 5, the control circuit 17 determines the operation condition of the probe laser light source 5 by adjusting the wavelength of the probe light to be emitted from the probe laser light source 5 based on the probe light intensity signal output from the amplifier 15.

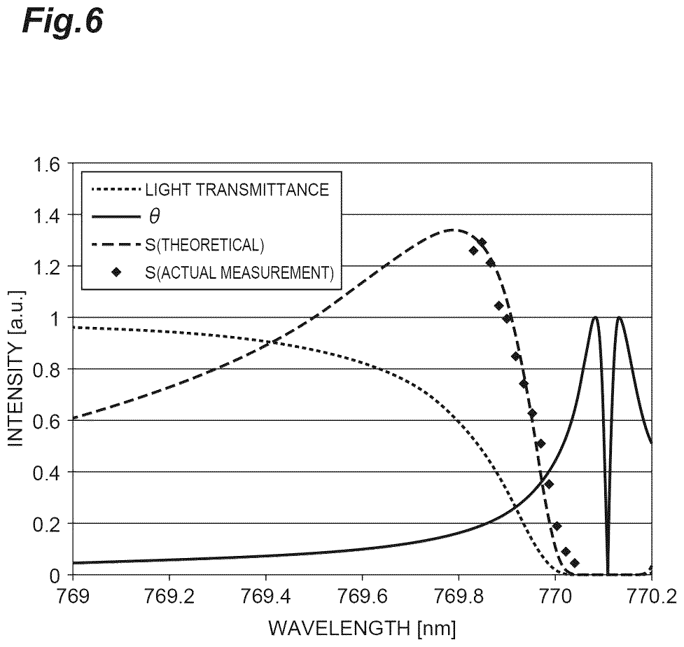

A specific example of determining the operation condition of the probe laser light source 5 will be described with reference to FIG. 6. FIG. 6 is a graph illustrating characteristics of an absorption cross section σ(ν) and a polarization rotation angle θ of alkali metal with respect to a wavelength ν of probe light, and characteristics of an intensity S of a magnetism detection signal with respect to the wavelength ν of probe light. The absorption cross section σ(ν) and the polarization rotation angle θ of the alkali metal have a relationship expressed by the following Theoretical Formulas (1) and (2) with respect to the wavelength ν of the probe light.

$$[ Formula 1 ]$$

$$σ ( v ) = {r}_{e} c f \frac{Γ / 2}{{( v - {v}_{0} )}^{2} + {( Γ / 2 )}^{2}} \qquad ( 1 )$$

$$[ Formula 2 ]$$

$$θ = {ncr}_{e} f \frac{v - {v}_{0}}{{( v - {v}_{0} )}^{2} + {( Γ / 2 )}^{2}} {l}_{cross} {S}_{X} \qquad ( 2 )$$

In the above Formulas (1) and (2), n represents the number of atoms of the alkali metal atom per unit volume, c represents the speed of light, rₑ represents the classical electron radius, f represents the oscillator strength which is a constant for each absorption line of an atom, ν₀ represents the absorption frequency of the alkali metal atom, Γ represents the absorption spectrum line width, l_{cross} represents the optical path length, and S_{X} represents the x-axis direction component of the spin polarization. The intensity S of the magnetism detection signal is represented by the following Theoretical Formula (3);

$$S ∝ exp ( - n σ {l}_{c r o s s} ) \times θ \qquad ( 3 )$$

and the intensity is proportional to the value obtained by multiplying the light transmittance by the polarization rotation angle.

Using the above theoretical formula, the control circuit 17 measures the wavelength characteristic of the voltage value of the probe light intensity signal while performing wavelength sweeping on the probe light, obtains Theoretical Formula (1) that approximates to the wavelength characteristic, and specifies the unknown parameter Γ in the obtained Theoretical Formula (1). Then, the control circuit 17 calculates a theoretical value of the wavelength characteristic of the intensity S by applying the specified Γ to Theoretical Formulas (2) and (3). Further, the control circuit 17 calculates the value of the absorption cross section σ when the theoretical value of the calculated wavelength characteristic of the intensity S has the maximum value, and determines the operation condition of the probe laser light source 5 so that the probe light intensity signal output from the amplifier 15 has a voltage value of the light transmittance corresponding to the calculated value. This makes it possible to set the wavelength of the probe light to a state in which the sensitivity of the magnetism detection signal is high regardless of variations in the characteristics of the cell 2.

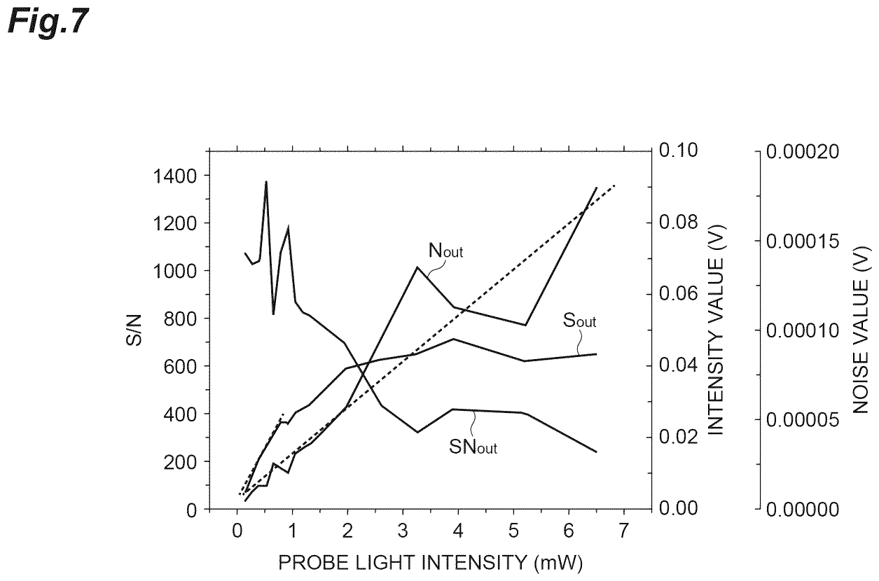

In addition, as a function of determining the operation condition of the probe laser light source 5, the control circuit 17 determines the operation condition of the probe laser light source 5 by adjusting the intensity of the probe light to be emitted from the probe laser light source 5 based on the probe light intensity signal output from the amplifier 15. FIG. 7 is a graph illustrating a relationship between probe light intensity and an intensity value Sₒᵤₜ of a magnetism detection signal, a noise value Nₒᵤₜ of the magnetism detection signal, and a value SNₒᵤₜ of an SN ratio of the magnetism detection signal. As indicated, in the output of the magnetometer module 1, the SN ratio deteriorates when the intensity of the probe light becomes excessively high. The control circuit 17 determines the operation condition of the probe laser light source 5 so that the probe light intensity signal output from the amplifier 15 has a voltage value corresponding to a value (for example, 100 mW/cm²) at which the SN ratio does not deteriorate. This makes it possible to set the intensity of the probe light to a state in which the quality of the magnetism detection signal is high regardless of variations in the characteristics of the cell 2.

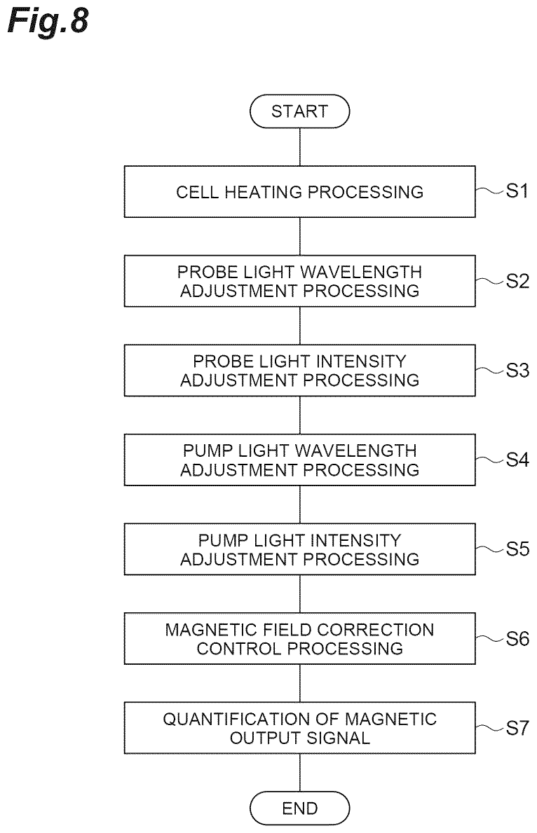

Hereinafter, with reference to FIG. 8, the procedure of the preparation operation in the magnetometer module 1 will be described, and the method for determining an operation condition according to the embodiment will be described in detail.

First, when the operation of the magnetometer module 1 is started, the control circuit 17 controls the supply current to the heater 3 to start cell heating processing so that the temperature inside the cell 2 becomes a predetermined temperature (Step S1). Next, the control circuit 17 executes the function of determining the operation condition of the probe laser light source 5, thereby adjusting the wavelength of the probe light (Step S2). Further, the control circuit 17 executes the function of determining the operation condition of the probe laser light source 5, thereby adjusting the intensity of the probe light (Step S3).

Thereafter, the control circuit 17 executes the function of determining the operation condition of the pump laser light source 4, thereby adjusting the wavelength of the pump light (Step S4). Next, the control circuit 17 executes the function of determining the operation condition of the pump laser light source 4, thereby adjusting the intensity of the pump light (Step S5). Further, the control circuit 17 executes the function of controlling the magnetic field correction, thereby controlling the magnetic field correction in the three axis directions with the magnetic field correction coil 10 (Step S6). Finally, in the control circuit 17, processing of quantifying the external output value of the magnetism detection signal is executed in a state where the magnetism reference signal is applied to the cell 2 (Step S7).

In the preparation operation described above, the intensities of the probe light and the pump light are adjusted after the wavelengths of the probe light and the pump light are adjusted. This facilitates optimization of the operation conditions of the light sources. The control of the correction magnetic field is executed after the adjustment of the probe light and the pump light. This makes it possible to improve the accuracy of correction of the environmental magnetic field at the time of actual magnetic field detection with the magnetometer module 1.

The operational effects of the magnetometer module 1 according to the embodiment described above will be described.

According to the magnetometer module 1, the intensity of the pump light emitted from the pump laser light source 4 toward the cell 2 is detected by the photodiode 13, the intensity of the probe light emitted from the probe laser light source 5 toward the cell 2 is detected by the photodiode element 9a, and a magnetism detection signal related to magnetism is generated based on the probe light having passed through the cell 2. In the magnetometer module 1, both the processing of determining the operation condition of the pump laser light source 4 based on the intensity of the pump light while performing wavelength sweeping on the pump light and the processing of determining the operation condition of the probe laser light source 5 based on the intensity of the probe light while performing wavelength sweeping on the probe light are performed. This makes it possible to set the both light sources in an appropriate operation condition even though a change occurs in the state of the cell, and the measurement sensitivity can be enhanced according to a change in the state of the cell.

The determination processing for the operation condition of the pump laser light source 4 is processing of determining the operation condition of the first light source to obtain the intensity of the pump light having a local minimum value. This makes it possible to set the operation condition of the light source so as to increase the spin polarization of the alkali metal and reliably enhance the measurement sensitivity.

The determination processing for the operation condition of the probe laser light source 5 is processing of measuring the wavelength characteristic of the intensity of the probe light, calculating the wavelength characteristic of the output signal from the wavelength characteristic, and determining the operation condition of the second light source to obtain the wavelength characteristic of the output signal having a local maximum value. This makes it possible to set the operation condition of the light source so as to increase the magnetism detection signal and reliably enhance the measurement sensitivity.

In addition, the magnetic field correction coil 10 that corrects the magnetic field in the space where the cell 2 is present is further provided, and the control circuit 17 further performs processing of controlling the magnetic field correction with the magnetic field correction coil 10 based on the intensity of the pump light. This makes it possible to correct the residual magnetic field such as geomagnetism in the cell and further enhance the measurement sensitivity. At this time, the control circuit 17 controls the correction with the magnetic field correction coil 10 so that the intensity of the pump light has an extreme value. Such control makes it possible to correct and cancel the residual magnetic field such as geomagnetism in the cell and further enhance the measurement sensitivity.

Although various embodiments of the present invention have been described above, the present invention is not limited to the above embodiments, and may be modified or applied to other objects without changing the gist described in each claim.

For example, in the above embodiment, either one of the processing of determining the operation condition of the pump laser light source 4 based on the intensity of the pump light while performing wavelength sweeping on the pump light and the processing of determining the operation condition of the probe laser light source 5 based on the intensity of the probe light while performing wavelength sweeping on the probe light may be performed. In this case as well, one of the light sources can be set in an appropriate operation condition even though a change occurs in the state of the cell, and the measurement sensitivity can be enhanced according to a change in the state of the cell.

In the above embodiment, the differential amplifier 16 may be used as an amplifier that amplifies and outputs the probe light intensity signal. In such a configuration, a shutter that blocks a component of the probe light incident on either the photodiode element 9a or the photodiode element 9b is provided, and the operation of the shutter is controlled so as to block the component of the probe light when outputting the probe light intensity signal.

In the first aspect of the embodiment, the first determination processing is preferably processing of determining a driving condition of the first light source so that the intensity of the pump light has a local minimum value. This makes it possible to set the driving condition of the first light source so as to increase the spin polarization of the alkali metal and reliably enhance the measurement sensitivity.

It is also preferable that the second determination processing is processing of measuring the wavelength characteristic of the intensity of the probe light, calculating the wavelength characteristic of the output signal from the wavelength characteristic, and determining the driving condition of the second light source so that the wavelength characteristic of the output signal has a local maximum value. This makes it possible to set the driving condition of the second light source so as to increase the output signal of the signal output unit and reliably enhance the measurement sensitivity.

Further, it is also preferable to further include a magnetic field correction coil that corrects the magnetic field in the space where the cell is present, and the control unit further performs processing of controlling the correction with the magnetic field correction coil based on the intensity of the pump light. This makes it possible to correct the residual magnetic field such as geomagnetism in the cell and further enhance the measurement sensitivity.

Further, it is also preferable that the control unit controls the correction with the magnetic field correction coil so that the intensity of the pump light has an extreme value. This makes it possible to correct and cancel the residual magnetic field such as geomagnetism in the cell and further enhance the measurement sensitivity.

The control unit preferably performs both the first determination processing and the second determination processing. In this case, both the first light source and the second light source can be set in suitable driving conditions, and the measurement sensitivity can be reliably enhanced according to the state change of the cell.

### REFERENCE SIGNS LIST

1 magnetometer module
2 Cell
4 Pump laser light source (first light source)
5 Probe laser light source (second light source)
9a Photodiode element (second detector)
13 Photodiode (first detector)
10 Magnetic field correction coil
16 Differential amplifier (signal output unit)
17 Control circuit (control unit)

1. A magnetometer module comprising:
a cell in which an alkali metal is enclosed;
a first light source configured to emit pump light for exciting an atom of the alkali metal;
a first detector configured to detect an intensity of the pump light;
a second light source configured to emit probe light for detecting a change in a magnetic rotation angle caused by spin polarization of the atom in an excited state;
a second detector configured to detect an intensity of the probe light;
a signal output device configured to detect a change in a polarization plane of the probe light based on the probe light having passed through the cell and generate an output signal related to magnetism in the cell; and
a controller configured to perform at least one of first determination processing of determining a driving condition of the first light source based on the intensity of the pump light detected by the first detector while controlling the first light source and performing wavelength sweep on the pump light and second determination processing of determining a driving condition of the second light source based on the intensity of the probe light detected by the second detector while controlling the second light source and performing wavelength sweep on the probe light.

2. The magnetometer module according to claim 1, wherein
the first determination processing is processing of determining a driving condition of the first light source to obtain the intensity of the pump light having a local minimum value.

3. The magnetometer module according to claim 1, wherein
the second determination processing is processing of measuring a wavelength characteristic of the intensity of the probe light, calculating a wavelength characteristic of the output signal from the wavelength characteristic, and determining a driving condition of the second light source to obtain the wavelength characteristic of the output signal having a local maximum value.

4. The magnetometer module according to claim 1, further comprising
a magnetic field correction coil configured to correct a magnetic field in a space where the cell is present, wherein
the controller further performs processing of controlling correction with the magnetic field correction coil based on the intensity of the pump light.

5. The magnetometer module according to claim 4, wherein
the controller controls correction with the magnetic field correction coil to obtain the intensity of the pump light having an extreme value.

6. The magnetometer module according to claim 1, wherein
the controller performs both the first determination processing and the second determination processing.

7. A method for determining an operation condition of a magnetometer module, the magnetometer module including: a cell in which an alkali metal is enclosed; a first light source configured to emit pump light for exciting an atom of the alkali metal; a first detector configured to detect an intensity of the pump light; a second light source configured to emit probe light for detecting a change in a magnetic rotation angle caused by spin polarization of the atom in an excited state; a second detector configured to detect an intensity of the probe light; and a signal output device configured to detect a change in a polarization plane of the probe light based on the probe light having passed through the cell and generate an output signal related to magnetism in the cell, the method comprising at least one of:
performing first determination processing of determining a driving condition of the first light source based on the intensity of the pump light detected by the first detector while controlling the first light source and performing wavelength sweep on the pump light; and performing second determination processing of determining a driving condition of the second light source based on the intensity of the probe light detected by the second detector while controlling the second light source and performing wavelength sweep on the probe light.
